(19) United States
(12) Patent Application Publication
(10) Pub. No.: US 2013/0118564 A1
(43) Pub. Date: May 16, 2013

(54) RARE EARTH SULFIDE THIN FILMS

(71) Applicants: Chin Li Cheung, Lincoln, NE (US); Joseph R. Brewer, Beatrice, NE (US)

(72) Inventors: Chin Li Cheung, Lincoln, NE (US); Joseph R. Brewer, Beatrice, NE (US)

(21) Appl. No.: 13/639,731

(22) PCT Filed: Apr. 6, 2011
(86) PCT No.: PCT/US11/31454

§ 371 Date: Jan. 28, 2013

Related U.S. Application Data
(60) Provisional application No. 61/321,375, filed on Apr. 6, 2010.

(51) Int. Cl. H01L 31/0328; H01L 31/18

(52) U.S. Cl. CPC H01L 31/0328; H01L 31/1828
USPC 136/252; 438/95

(57) ABSTRACT

An apparatus that includes a photovoltaic cell is provided. The photovoltaic cell includes a p-type thin film having a first rare earth sulfide, and an n-type thin film having a second rare earth sulfide. A p-n junction is formed between the p-type thin film and the n-type thin film. The photovoltaic cell includes a substrate and an at least partially transparent layer. The p-type and n-type thin films are deposited between the substrate and the at least partially transparent layer.

### CROSS-REFERENCE TO RELATED APPLICATIONS

This application is claims priority to U.S. Provisional Application Ser. No. 61/321,375, filed on Apr. 6, 2010, which is incorporated herein by reference in its entirety.

### TECHNICAL FIELD

This subject matter is generally related to rare earth sulfide thin films.

### BACKGROUND

Photovoltaic (PV) devices can be used to convert solar energy to electricity. For example, a photovoltaic device can have a layer of n-type semiconducting material and a layer of p-type semiconducting material. When the photovoltaic device absorbs light having energy equal to or higher than the bandgap of the semiconducting material, the incoming photons excite electrons to move from the valence band to the conduction band. The electric field at the p-n junction causes the electrons and holes to migrate toward the positive and negative sides, respectively, of the junction, generating an electric current when the photovoltaic device is connected to an electric circuit. Several types of materials have been used in photovoltaic devices, such as crystalline and polycrystalline silicon, cadmium telluride (CdTe), copper indium gallium selenide (CIGS), gallium arsenide (GaAs), light absorbing dyes, and organic polymers.

### SUMMARY

In general, in one aspect, an apparatus that includes a photovoltaic cell is provided. The photovoltaic cell includes a p-type thin film having a first rare earth sulfide, and an n-type thin film having a second rare earth sulfide. A p-n junction is formed between the p-type thin film and the n-type thin film. The photovoltaic cell includes a substrate and an at least partially transparent layer. The p-type and n-type thin films are deposited between the substrate and the at least partially transparent layer.

Implementations of the apparatus may include one or more of the following features. Each of the first and second rare earth sulfides can include a rare earth sesquisulfide (RE₂S₃) or polysulfide (RE₃S₄). The first rare earth sulfide can include samarium, and the second rare earth sulfide can include yttrium, lanthanum, cerium, praseodymium, neodymium, gadolinium, terbium, dysprosium, or holmium. The p-type thin film can include samarium sulfide doped with calcium, barium, or europium. The n-type thin film can include lanthanum sulfide doped with cerium(IV). A growth layer can be formed on the substrate, and one of the p-type or n-type thin film can be formed on the growth layer. The growth layer can include zirconium nitride or titanium nitride. The substrate can be made of a conductive or semi-conductive material (e.g., silicon). The n-type thin film can be closer to the at least partially transparent layer than the p-type thin film. The p-type thin film can include a phase-pure rare earth sulfide. The p-type phase-pure rare earth sulfide can include samarium sesquisulfide (Sm₂S₃) and/or samarium polysulfide (Sm₃S₄), and contain little or none of samarium monosulfide (SmS). The n-type thin film can include a phase-pure rare earth sulfide. The n-type phase-pure rare earth sulfide can include lanthanum sesquisulfide (La₂S₃) and/or lanthanum polysulfide (La₃S₄), and contain little or none of lanthanum monosulfide (LaS).

In general, in another aspect, an apparatus includes a substrate, and a p-type semiconducting layer on the substrate. The p-type semiconducting layer includes samarium sulfide nanowires.

Implementations of the apparatus may include one or more of the following features. A growth layer can be formed on the substrate, and the p-type semiconducting layer can be formed on the growth layer. The growth layer can include zirconium nitride or titanium nitride. The samarium sulfide nanowires can include samarium sesquisulfide (Sm₂S₃) or polysulfide (Sm₃S₄) nanowires.

In general, in another aspect, an apparatus including an organic photovoltaic cell that has a substrate, a polymer film, a p-type semiconducting layer, and an at least partially transparent layer is provided. The p-type semiconducting layer includes nanowires having samarium sulfide. The polymer film and the p-type semiconducting layer are deposited between the substrate and the at least partially transparent layer.

Implementations of the apparatus may include one or more of the following features. A growth layer can be formed on the substrate, and the p-type semiconducting layer can be formed on the growth layer. The growth layer can include zirconium nitride or titanium nitride. The samarium sulfide can include samarium sesquisulfide (Sm₂S₃) or polysulfide (Sm₃S₄).

In general, in another aspect, a method includes providing a growth layer on a substrate; heating the substrate and the growth layer; heating sulfur to form sulfur vapor; heating samarium halide to form samarium halide vapor; and forming a thin film of samarium sulfide on the growth layer, the samarium sulfide being generated from the sulfur and the samarium halide.

Implementations of the method may include one or more of the following features. The samarium halide can include samarium chloride, samarium iodide, or samarium bromide. The growth layer can be a zirconium nitride layer or a titanium nitride layer. The substrate can be conductive or semi-conductive. The samarium sulfide can include samarium sesquisulfide or samarium polysulfide. The sulfur can be heated in a first chamber at a first temperature, and the samarium halide can be heated in a second chamber at a second temperature, in which the second temperature is higher than the first temperature. The temperature of the first chamber is controlled to control a stoichiometry and growth rate of the samarium sulfide thin film. The sulfur can be placed in an upstream heating chamber, and the substrate and the samarium halide can be placed in a downstream heating chamber, the downstream heating chamber having a temperature higher than that of the upstream heating chamber.

In general, in another aspect, a method includes providing a growth layer on a substrate; heating the substrate and the growth layer; heating sulfur to form sulfur vapor; heating samarium halide to form samarium halide vapor; and forming a textured film having samarium sulfide nanowires on the growth layer. The samarium sulfide nanowires are generated from the sulfur and the samarium halide.

Implementations of the method may include one or more of the following features. The growth layer can be a zirconium nitride layer or a titanium nitride layer. The samarium sulfide can include samarium sesquisulfide or samarium polysulfide. The samarium halide can include samarium chloride, samarium iodide, or samarium bromide.

In general, in another aspect, a method includes providing a growth layer on a substrate; heating the substrate and the growth layer; heating samarium halide to form samarium halide vapor; providing hydrogen sulfide; and forming a thin film of samarium sulfide on the growth layer, the samarium sulfide being generated from the sulfur and the samarium halide.

Implementations of the apparatus may include one or more of the following features. The growth layer can include a zirconium nitride layer or a titanium nitride layer. The flow rate of the hydrogen sulfide can be controlled to control a stoichiometry and growth rate of the samarium sulfide thin film. The samarium sulfide can include samarium sesquisulfide or samarium polysulfide. The samarium halide can include samarium chloride, samarium iodide, or samarium bromide.

In general, in another aspect, a method includes providing a growth layer on a substrate; heating the substrate and the growth layer; heating samarium halide to form samarium halide vapor; providing hydrogen sulfide; and forming a textured film having samarium sulfide nanowires on the growth layer. The samarium sulfide nanowires are generated from the sulfur and the samarium halide.

Implementations of the method may include one or more of the following features. The growth layer can be a zirconium nitride layer or a titanium nitride layer. The samarium sulfide can include samarium sesquisulfide or samarium polysulfide. The samarium halide can include samarium chloride, samarium iodide, or samarium bromide.

In general, in another aspect, a method of fabricating a photovoltaic cell is provided. The method includes providing a growth layer on a substrate; forming a samarium sulfide thin film on the growth layer; forming an n-type thin film on the samarium sulfide thin film, in which a p-n junction is formed between the n-type thin film and the samarium sulfide thin film; and providing an at least partially transparent layer on the n-type thin film.

Implementations of the method may include one or more of the following features. The growth layer can be a zirconium nitride layer or a titanium nitride layer. The samarium sulfide can include samarium sesquisulfide or samarium polysulfide. The n-type thin film can include an n-type rare earth sulfide thin film. The n-type thin film can include a rare earth sulfide thin film having yttrium, lanthanum, cerium, praseodymium, neodymium, gadolinium, terbium, dysprosium, or holmium.

In general, in another aspect, a method of fabricating an organic photovoltaic cell is provided. The method includes providing a growth layer on a substrate; forming a textured layer having samarium sulfide nanowires on the growth layer; forming a polymer layer on the textured layer; and providing an at least partially transparent layer on the polymer layer.

Implementations of the method may include one or more of the following features. The growth layer can include a zirconium nitride layer or a titanium nitride layer. The samarium sulfide can include samarium sesquisulfide or samarium polysulfide.

In general, in another aspect, a method includes providing at least one of a zirconium nitride layer or a titanium nitride layer on a substrate; providing sulfur vapor; providing rare earth halide vapor; and generating a rare earth sulfide thin film on the zirconium nitride layer or the titanium nitride layer. The rare earth sulfide is formed based on a reaction between the sulfur vapor and the rare earth halide vapor.

Implementations of the method may include one or more of the following features. The rare earth chloride vapor can include samarium, yttrium, lanthanum, cerium, praseodymium, neodymium, gadolinium, terbium, dysprosium, or holmium. The rare earth sulfide can include a rare earth sesquisulfide or a rare earth polysulfide. The rare earth halide vapor can include samarium chloride vapor, samarium iodide vapor, or samarium bromide vapor.

### DESCRIPTION OF DRAWINGS

FIG. 1 is a schematic diagram of a photovoltaic device.

FIG. 2 is a schematic diagram of a dual-furnace chemical vapor deposition system.

FIG. 3A is a scanning electron microscope image of a Sm₂S₃ thin film.

FIG. 3B is a scanning electron microscope image of a layer of samarium sesquisulfide nanowires.

FIG. 3C is a graph showing an x-ray diffraction pattern of a layer samarium sesquisulfide nanowires.

FIG. 4 is a graph showing the Raman spectrum 182 of the Sm₂S₃ thin film.

FIG. 5 is a schematic diagram of a chemical vapor deposition system for depositing rare earth sulfide thin films.

FIGS. 6A to 6C are graphs of x-ray diffraction patterns of samarium sulfide thin films.

FIGS. 7A to 7C are scanning electron microscope images of Sm₂S₃ crystals.

FIGS. 8A to 8C are graphs of x-ray diffraction patterns of lanthanum sulfide thin films.

FIG. 9 is a schematic diagram of an organic photovoltaic device.

FIG. 10 is a diagram illustrating bound electron-hole pair diffusion in an organic photovoltaic device.

FIG. 11 is a diagram showing decomposition of bound charge carriers at a nanostructured interface.

### DETAILED DESCRIPTION

Rare earth sesquisulfide (RE₂S₃) and rare earth polysulfide (RE₃S₄) have low work function and high melting points. Their optoelectronic and structural properties make them good optoelectronic materials. They have a range of electronic properties from semiconducting to metallic, band gaps in the range of 1.6 eV to 3.7 eV. For example, p-type samarium sesquisulfide (Sm₂S₃) has a band gap in the range of 1.7 eV to 1.9 eV and n-type lanthanum sesquisulfide (La₂S₃) has a band gap of about 2.7 eV. The band gaps of p-type Sm₂S₃ and n-type La₂S₃ have values that make these semiconducting materials suitable for thin film photovoltaic applications.

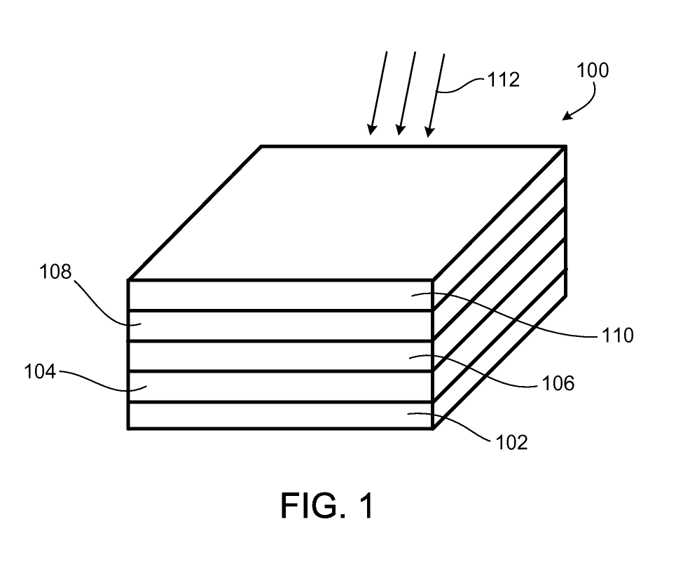

Referring to FIG. 1, in some implementations, a photovoltaic device 100 includes a substrate 102, a growth layer 104, a layer of p-type rare earth sulfide 106, a layer of n-type rare earth sulfide 108, and a layer of transparent conductive oxide 110. The substrate 102 can be made of an insulating, conducting, or semiconducting material, such as silicon. The growth layer 104 helps the deposition of the p-type rare earth sulfide to improve the quality of the p-type rare earth sulfide thin film. The growth layer 104 can be made of, e.g., zirconium nitride (ZrN) or titanium nitride (TiN). The thickness of the zirconium nitride or titanium nitride growth layer can be, e.g., 500 nm or more. The transparent conductive oxide 110 can be, e.g., indium tin oxide (ITO).

The growth layer 104 can act as a barrier to prevent the surface of the substrate 102 from reacting with materials that are present during deposition of the rare earth sulfide 106. For example, if the substrate is made of silicon, silicide may be formed on the surface of the silicon substrate, affecting the deposition of the p-type rare earth sulfide. If the substrate is intended to be used as an electrode, a junction may be formed between the silicide and the substrate, affecting the function of the substrate as an electrode. A zirconium nitride growth layer can prevent the formation of silicide on the surface of the silicon substrate. The zirconium nitride and the titanium nitride are good conductive materials and will not affect the function of the silicon substrate as an electrode.

In some examples, if the substrate is made of a material that is stable and does not react with other materials that are present during deposition of the rare earth sulfide, it may not be necessary to use an additional growth layer on the substrate.

The p-type rare earth sulfide 106 can be, e.g., samarium sulfide, such as samarium sesquisulfide (Sm₂S₃) or samarium polysulfide (Sm₃S₄). The n-type rare earth sulfide 108 can be, e.g., lanthanum sesquisulfide (La₂S₃) or lanthanum polysulfide (La₃S₄). Other rare earth materials, such as yttrium, cerium, praseodymium, neodymium, gadolinium, terbium, dysprosium, and holmium, can also be used for the n-type rare earth sulfide 108.

In some examples, the p-type rare earth sulfide 106 is a phase-pure rare earth sulfide RESₓ (x=1.3 to 1.5), meaning that the rare earth sulfide includes rare earth sesquisulfide (RE₂S₃) and/or rare earth polysulfide (RE₃S₄) but has very little or none of rare earth monosulfide (RES). For example, a layer of phase-pure SmSₓ (x=1.3 to 1.5) is substantially composed of samarium sesquisulfide (Sm₂S₃) and/or samarium polysulfide (Sm₃S₄), and has very little or none of samarium monosulfide (SmS). The RE₂S₃ crystal structure is the substantially the same as the RE₃S₄ structure except that the RE₂S₃ structure has metal vacancies. Thus, RE₂S₃ and RE₃S₄ can be considered the same phase. In some implementations, the rare earth sulfides synthesized according to the process described here can have a structure in the range between RE₂S₃ and RE₃S₄.

In some examples, the n-type rare earth sulfide 108 is a phase-pure rare earth sulfide RESₓ (x=1.3 to 1.5). For example, a layer of phase-pure LaSₓ (x=1.3 to 1.5) is substantially composed of lanthanum sesquisulfide (La₂S₃) and/or lanthanum polysulfide (La₃S₄), and has very little or none of lanthanum monosulfide (LaS). Because different phases of a rare earth sulfide may have different electrical properties, depositing a layer of phase-pure rare earth sulfide may allow better control of the electrical properties of the layer.

In some examples, the n-type and p-type rare earth sulfides can include a mixture of two or more of rare earth monosulfide (RES), rare earth sesquisulfide (RE₂S₃), and rare earth polysulfide (RE₃S₄).

Light rays 112 enter the photovoltaic device 100 from the transparent conductive oxide layer 110 side. Typically, the n-type material 108 is selected to have a band gap larger than the p-type material 106. Photons having energy less than the band gap of the n-type material but larger than the band gap of the p-type material pass the n-type layer 108 and are absorbed at the p-type layer 106, causing electrons to be excited from the valence band to the conduction band.

An advantage of using rare earth sulfides for both the p-type and n-type materials is that the photovoltaic device 100 can be produced at a lower cost than other types of solar cells, such as cadmium-telluride solar cells. According to recent reports, rare earth materials such as samarium and lanthanum are more abundant than cadmium and tellurium. The rare earth sulfides have band gaps that are suitable for absorbing photons in sunlight.

The structural and compositional characterizations of rare earth sesquisulfides are generally complicated due to the existence of their six different crystal structures: α, β, γ, δ, ε, and τ phases. The formation of the different phases depends on the temperature of synthesis and ionic radius of the rare earths. The low temperature phase of RE₂S₃ is the α-phase which has an orthorhombic structure (Pnma). The β-phase has a tetragonal structure (I4₁/acd), similar as those of ternary RE₁₀SO₁₋ₓSₓ (0≦x≦1). The γ-phase is the high temperature phase which has a cubic defective Th₃P₄-type structure ( [symbol] ). The δ-phase has the monoclinic structure (P2₁/m). The ε-phase has the trigonal corundum-type structure (z,999 ). The τ-phase has the cubic bixbyite-type structure (Ia3)). It may be difficult to distinguish γ-phase RE₂S₃ and RE₃S₄ because RE₂S₃ compounds are isostructural with the RE₃S₄ compounds. The RE₂S₃ structure can be obtained from that of RE₃S₄ by introducing vacancies at random on the RE cation sites.

The electrical properties of rare earth sesquisulfides are different from those of rare earth polysulfides. Rare earth sesquisulfides are a class of semiconducting materials that have photoconductivity properties similar to cadmium sulfide (CdS). Their resistivity ranges from 0.1 to 0.02 Ω-cm, similar to that other optoelectronic materials such as CdS (0.1 to 0.9 Ω-cm), and lower than that of copper indium gallium selenide (CIGS) (1 to 35 Ω-cm) or germanium (about 100 Ω-cm). Rare earth polysulfide materials are metallic phase materials that have resistivity in the 10⁻⁴ Ω-cm range. It may be possible to achieve lattice matching between the different rare earth metals and different sulfide phases, making these materials analogous to lattice matched optoelectronic systems such as indium gallium arsenide (InGaAs), indium gallium nitride (InGaN), and indium gallium antimonide (InGaSb).

Due to their low resistance and desirable optical band gaps and lattice matching properties, RE₂S₃ and RE₃S₄ thin films present a class of conductive electron and hole transport electrode materials that have unique optoelectronic device applications. The phase, crystallinity, and material properties of RE₂S₃ and RE₃S₄ can be controlled to form homogenous mixtures that have a wide range of crystal structures (e.g., cubic and rhombohedral structures).

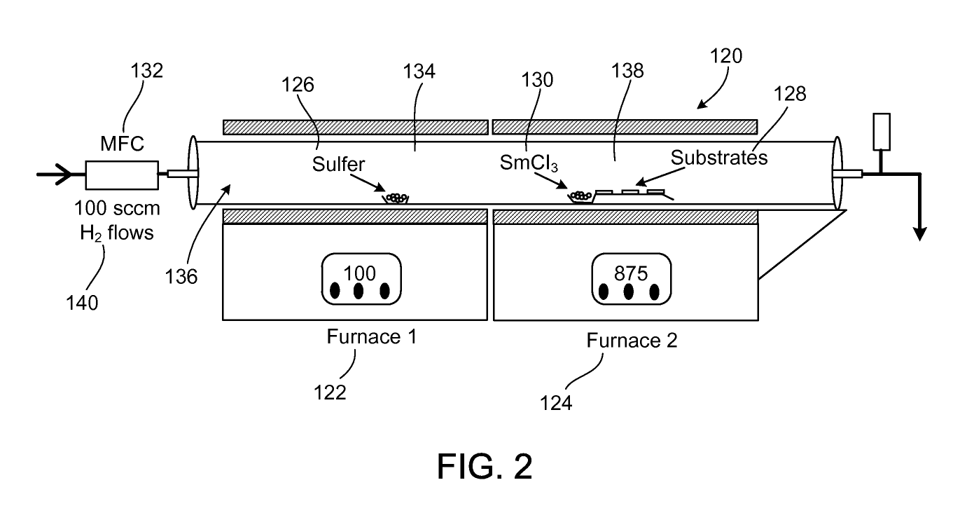

Referring to FIG. 2, high purity rare earth sulfide thin films can be produced using a dual-furnace chemical vapor deposition (CVD) system 120. In a chamber 136, sulfur 126 is placed in a first section 134 of the chamber 136 heated by a first furnace 122. A rare earth source 130 and one or more substrates 128 are placed in a second section 138 of the chamber 136 heated by a second furnace 124. The rare earth source 130 can be, e.g., a rare earth chloride, such as samarium chloride (SmCl₃). When fabricating a photovoltaic device, the substrate 128 is selected to be a conductive or semi-conductive material (e.g., silicon) that serves as an electrode. For other applications, the substrate 128 can be made of other materials, such as quartz or lanthanum aluminum oxide (LaAlO₃). The substrate 128 has a growth layer on its surface, in which the growth layer can be made of, e.g., zirconium nitride or titanium nitride.

In some implementations, air is pumped out of the chamber 136 until the pressure in the chamber 136 is about 1 to 4 milliTorr. This reduces the amount of oxygen that may react with some of the materials and affect the deposition of the samarium sulfide thin film. A flow of hydrogen gas (H₂) 140 is provided in the chamber 136, and a mass flow controller 132 controls the amount of hydrogen gas 140 flowing into the chamber 136. The sulfur 126 is placed at upstream of the rare earth source 130, which is placed at a location upstream of and near the substrate 128. The first furnace 122 heats the sulfur 126 to generate sulfur vapor, and the second furnace 124 heats the rare earth chloride 130 to generate rare earth chloride vapor. When the sulfur vapor and the samarium chloride vapor are generated, and the hydrogen gas is provided to the chamber 136, the pressure in the chamber 136 can be about 100 to 200 milliTorr. Maintaining the chamber 136 at a low pressure allows the samarium chloride to evaporate more easily. The sulfur vapor reacts with the rare earth chloride vapor to produce rare earth sulfide, which is deposited on the growth layer on the substrate 128. The chemical reaction for the formation of rare earth sesquisulfide in the chamber 136 can be represented as follows:

2RECl₃(g)+3S(g)+3H₂(g)→RE₂S₃(s)+6HCl(g)

where (g) represents gas phase and (s) represents solid phase.

In some examples, to generate samarium sesquisulfide (Sm₂S₃), the first furnace 122 heats the sulfur 126 to about 100° C., and the second furnace 124 heats the substrate 128 and the samarium chloride 130 to about 875° C. The mass flow controller 132 controls the flow of hydrogen gas 140 to about 100 standard cubic centimeter per minute (sccm). The temperatures of the first and second furnaces and the hydrogen gas flow rate described above are used as examples. When operating under different conditions, the temperatures of the furnaces and the hydrogen gas flow rate may be different from those provided above.

The temperature of the first furnace 122 controls the sulfur vapor pressure, the higher the temperature the higher the sulfur vapor pressure. In this example, the temperature of the first furnace 122 is lower than that of the second furnace 124. For example, where Sm₂S₃ is deposited on the growth layer of the substrates 128, the temperatures of the first and second furnaces are controlled such that the relative amounts of sulfur vapor and samarium chloride vapor facilitate the formation of high purity samarium sesquisulfide thin films on the substrates 128. By varying the temperatures of the first and second furnaces, it is possible to deposit a layer of rare earth sulfide having a high percentage of rare earth sesquisulfide, a layer of rare earth sulfide having a high percentage of rare earth polysulfide, or a layer of rare earth sulfide having a combination of rare earth sesquisulfide and rare earth polysulfide.

An advantage of this fabrication process is that there is little oxygen contamination. Instead of using samarium metal, which oxidizes rapidly in the air, this process uses samarium chloride, which is stable until it is heated into vapor form that reacts with sulfur vapor to form samarium sulfide. The rare earth sulfide thin films fabricated using this process have excellent adhesion to the substrates.

To fabricate the photovoltaic device 100 of FIG. 1, initially sulfur and samarium chloride are heated to form a layer of samarium sulfide on the growth layer on the substrate 128. The samarium chloride is then replaced by lanthanum chloride. The sulfur and the lanthanum chloride are heated to form a layer of lanthanum sulfide on the layer of samarium sulfide. The chamber 136 is maintained at a low pressure during deposition of the lanthanum sulfide to reduce the amount of oxygen in the chamber and to allow the lanthanum chloride to evaporate more easily.

By varying the temperature of the first and second furnaces 122, 124 and reaction duration, it is also possible to grow a forest of rare earth sulfide nanowires on the growth layer of the substrate 128 instead of a thin film of rare earth sulfide. For example, when the temperature of the first and second furnaces are increased (compared to the temperatures used for generating samarium sulfide thin films), samarium sulfide nanowires can be formed on the growth layer of the substrate 128. In some implementations, the rare earth sulfide nanowires can be used in organic photovoltaic devices, as described in more detail below.

In some examples, there may be a temperature gradient inside the chamber 136, so placing two substrates at different locations in the downstream section of the chamber may result in a samarium sulfide thin film being deposited in one substrate and samarium sulfide nanowires being deposited in another substrate.

After the rare earth nanowires are formed, the substrate having the nanowires is removed from the chamber and cooled down. Alternatively, the substrate may be left inside the chamber, and the chamber doors are opened to let in cool air. If the substrate having the nanowires is left inside the chamber 136 for an extended period of time and the chamber is allowed to cool down slowly, the nanowires may coagulate to form a thin film.

Without being bound by any theory presented herein, it is possible that at the higher temperature the samarium sulfide forms liquid droplets that function as nucleation sites, causing preferential deposition to form the nanowires. The range of temperatures for depositing rare earth thin films and the range of temperatures for depositing rare earth nanowires depend on the system. For different furnace and chamber designs, the temperature ranges may be different. The temperature is one of many parameters that may influence whether rare earth thin films or rare earth nanowires are formed. For example, the flux of chemical reactants may affect the growth of thin film or nanowires.

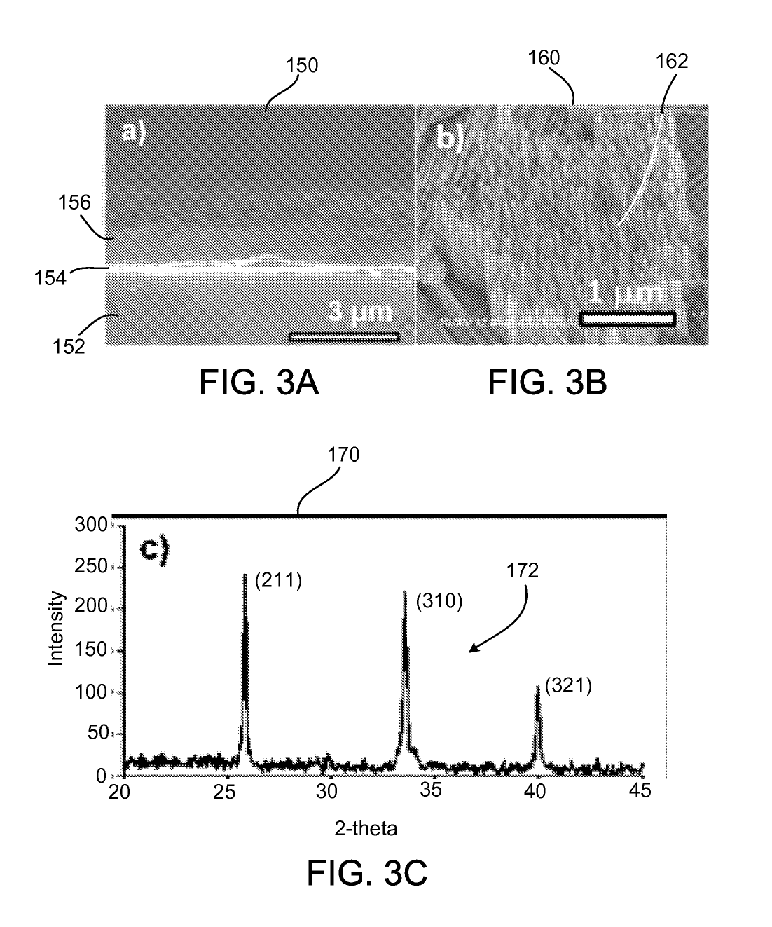

FIG. 3A is a scanning electron microscope image 150 of a Sm₂S₃ thin film fabricated using the dual-furnace CVD system 120. The image 150 shows a substrate 152, a growth layer 154, and a Sm₂S₃ thin film 156. The Sm₂S₃ thin film 156 has a thickness of about 2 to 3 μm. Hall effect and Van der Pauw measurements on the Sm₂S₃ thin film determined that the thin film has a hole mobility of about 3000 cm²V·s and a resistivity of about 0.02 Ω·cm. The hole mobility of the Sm₂S₃ thin film is similar to that of germanium, but the hole resistivity of the Sm₂S₃ thin film is lower than that of germanium. The resistivity the Sm₂S₃ thin film is also lower than those of copper indium gallium selenide (CIGS) (e.g., 1 to 35 Ω·cm) and cadmium sulfide (CdS) (e.g., 0.3 to 0.5 Ω·cm).

FIG. 3B is a scanning electron microscope image 160 of a layer of samarium sesquisulfide nanowires 162 fabricated using the dual-furnace CVD system 120. The Sm₂S₃ thin film shown in FIG. 3A and the Sm₂S₃ nanowires shown in FIG. 3B were fabricated using the dual-furnace CVD system 120 of FIG. 2. The sulfur 126 was heated at 100° C. furnace temperature, and the SmCl₃ source material was heated at 875° C. furnace temperature. A first substrate was placed about 2 cm from the SmCl₃ source material, and a second substrate was placed about 3 or 4 cm from the SmCl₃ source material (further downstream compared to the first substrate). A thin film of Sm₂S₃ was deposited on the first substrate, while Sm₂S₃ nanowires were formed on the second substrate. The local temperature of the second substrate is slightly higher than that of the first substrate due to a temperature gradient inside the horizontal tube furnace.

FIG. 3C is a graph 170 showing representative x-ray diffraction pattern 172 of the samarium sesquisulfide nanowires 162 in the image 160.

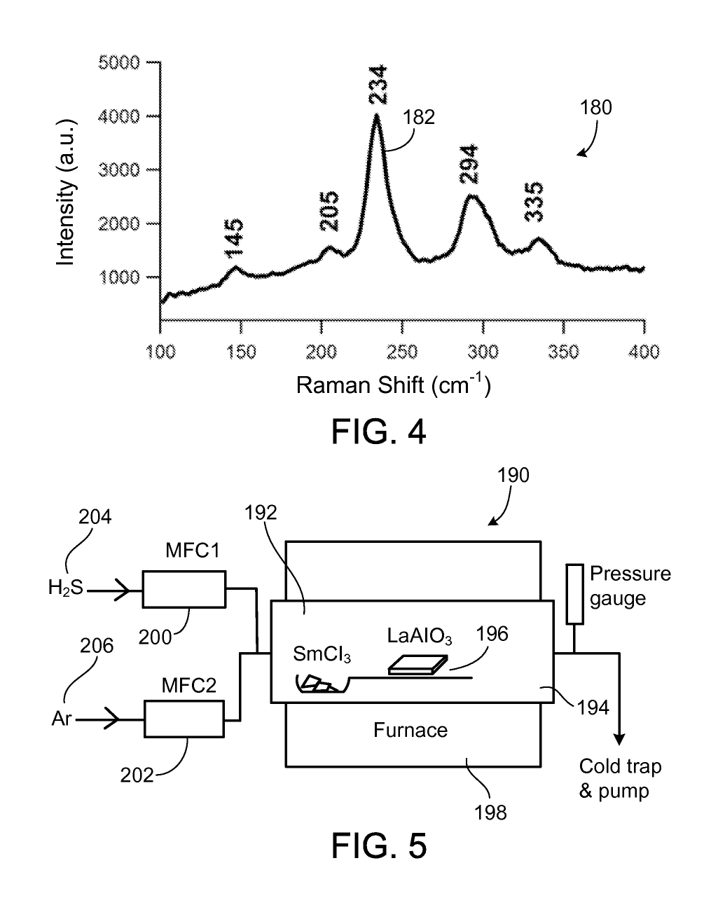

FIG. 4 is a graph 180 showing the Raman spectrum 182 of the Sm₂S₃ thin film 156 of FIG. 3A. The Raman spectrum 182 matches that of α-phase Sm₂S₃.

Referring to FIG. 5, in some implementations, 2% hydrogen sulfide balanced in argon can be used as the sulfur source. For example, rare earth chloride (RECl₃) and hydrogen sulfide (H₂S) can be used as the material precursors for fabricating rare earth sulfides in a single-furnace chemical vapor deposition system 190. For example, samarium chloride (SmCl₃.6H₂O) 192 is placed in a chamber 194 upstream of and near a substrate 196. In this example, the substrate 196 is made of lanthanum aluminum oxide (LaAlO₃).

In some implementations, air is pumped out of the chamber 194 until the pressure in the chamber is about 1 to 4 milliTorr. This reduces the amount of oxygen that may react with some of the materials and affect the deposition of the samarium sulfide thin film. Both the samarium chloride 192 and the substrate 196 are heated by a furnace 198 to about 1000° C. A first mass flow controller 200 controls the flow rate of 2% hydrogen sulfide (H₂S) gas 204 into the chamber 194 to about 0.5 to 4 sccm, and a second mass flow controller 202 controls the flow of argon (Ar) gas 206 into the chamber 194 to about 50 sccm. When the samarium chloride vapor is generated, and the hydrogen sulfide gas and the argon gas are provided to the chamber, the pressure in the chamber 194 can be about 100 to 200 milliTorr. Maintaining the chamber 194 at a low pressure allows the samarium chloride to evaporate more easily.

In this example, the overall chemical reaction equation is:

2SmCl₃(g)+3H₂S(g)→Sm₂S₃(s)+6HCl(g)

In this example, the lanthanum aluminum oxide (LaAlO₃) substrate is stable and does not react with the materials in the chamber 194, so it is not necessary to use an additional growth layer.

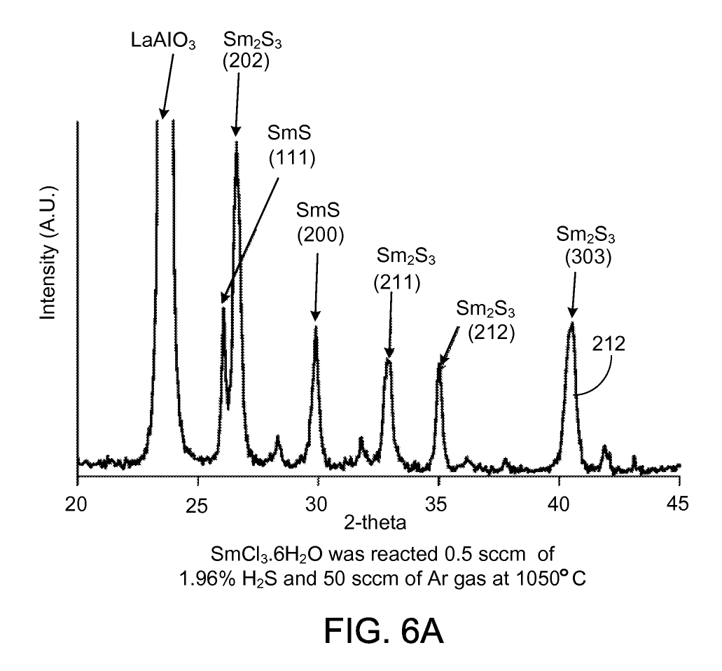

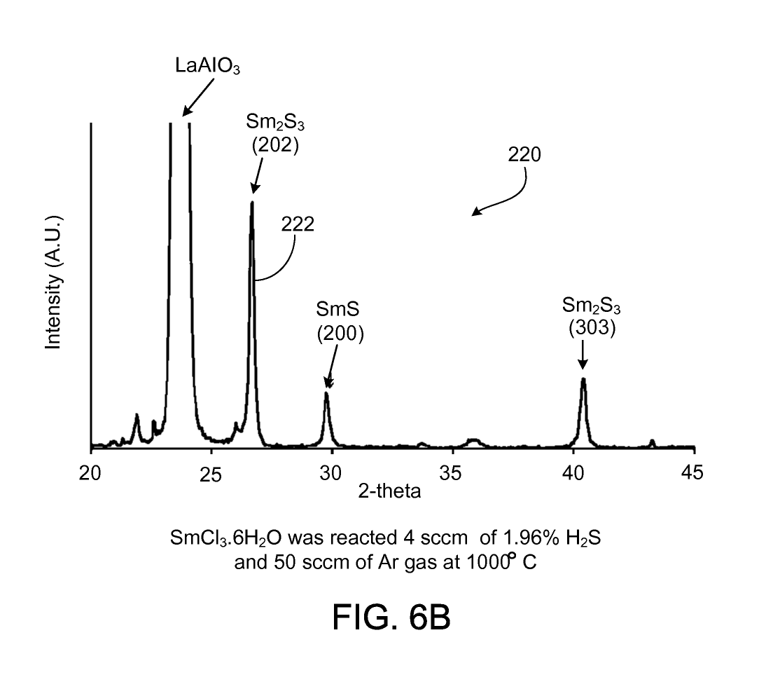

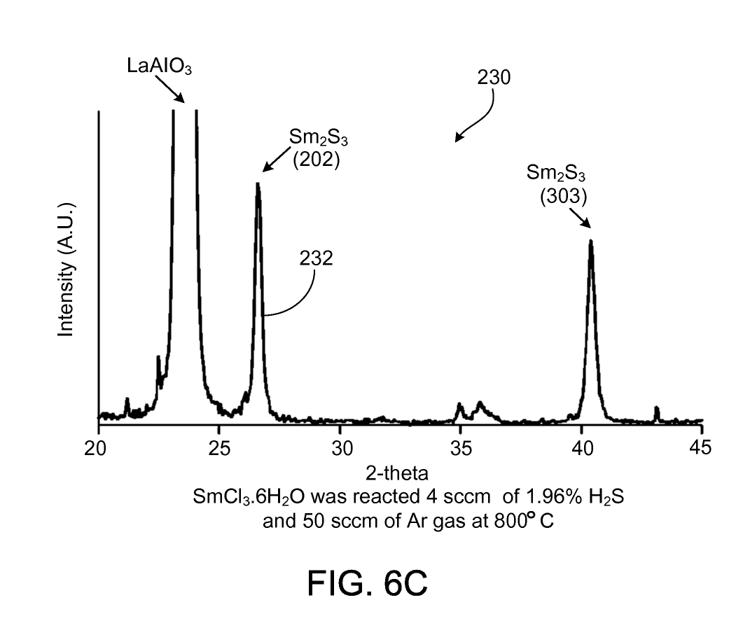

FIG. 6A is a graph 210 showing the x-ray diffraction pattern 212 of the samarium sulfide thin film generated using SmCl₃.6H₂O that reacted with 0.5 sccm of 2% H₂S gas at 1050° C., with a flow of 50 sccm of argon gas. The x-ray diffraction pattern 212 indicates the existence of SmS and Sm₂S₃ in the samarium sulfide thin film.

FIG. 6B is a graph 220 showing the x-ray diffraction pattern 222 of the samarium sulfide thin film generated using SmCl₃.6H₂O that reacted with 4 sccm of 2% H₂S gas at 1000° C., with a flow of 50 sccm of argon gas. The x-ray diffraction pattern 222 indicates the existence of SmS and Sm₂S₃ in the samarium sulfide thin film.

FIG. 6C is a graph 230 showing the x-ray diffraction pattern 232 of the samarium sulfide thin film generated using SmCl₃.6H₂O that reacted with 4 sccm of 2% H₂S gas at 800° C., with a flow of 50 sccm of argon gas. The x-ray diffraction pattern 232 indicates that the samarium sulfide thin film is mostly composed of Sm₂S₃. This demonstrates that the process described above can be used to deposit a phase-pure rare earth sulfide thin film, such as a layer of phase pure SmS (x=1.3 to 1.5) thin film that does not include other phases of samarium sulfide, such as SmS.

FIGS. 6A to 6C show that the stoichiometry of the samarium sulfide thin films (SmSₓ) can be controlled by varying the H₂S flow rates and furnace temperature. A higher furnace temperature and a lower flow rate of H₂S gas increase the formation of SmS in the samarium sulfide thin film.

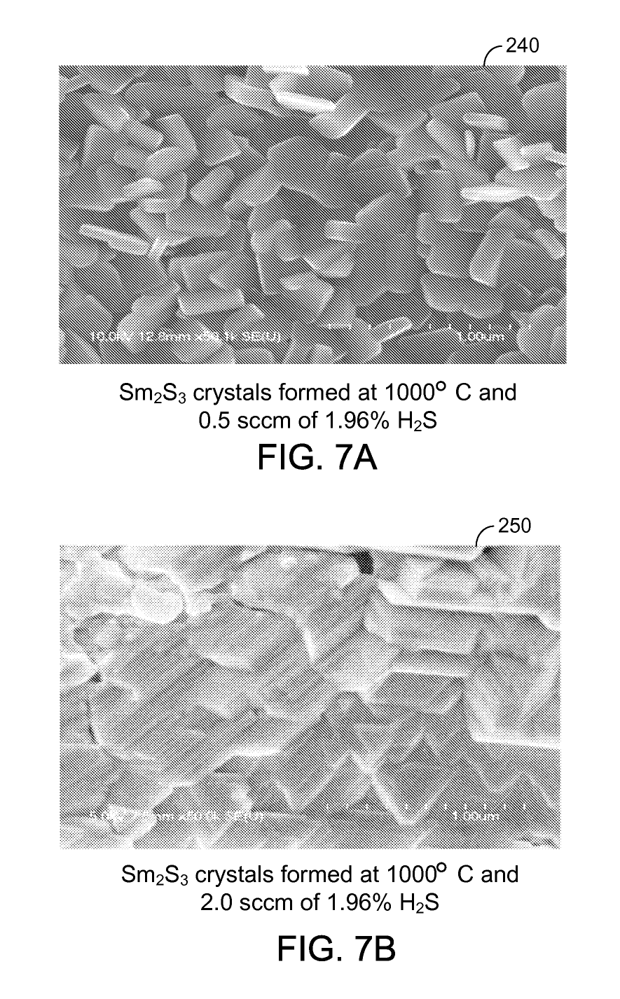

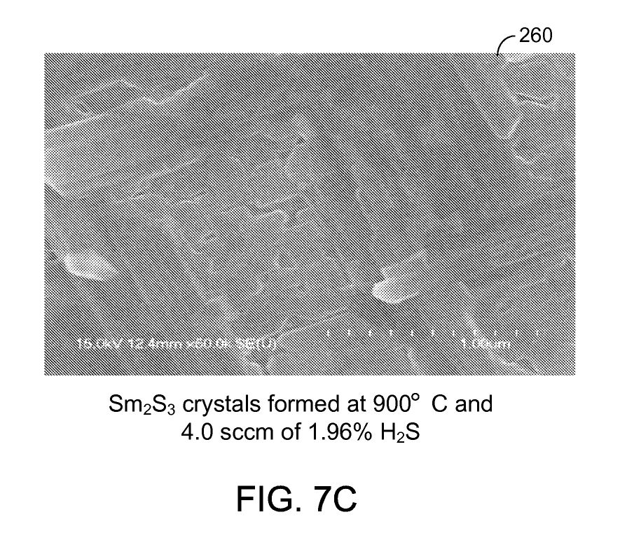

FIG. 7A is a scanning electron microscope image 240 of Sm₂S₃ crystals formed at 1000° C. with 0.5 sccm of 2% H₂S gas.

FIG. 7B is a scanning electron microscope image 250 of Sm₂S₃ crystals formed at 1000° C. with 2 sccm of 2% H₂S gas.

FIG. 7A is a scanning electron microscope image 260 of Sm₂S₃ crystals formed at 900° C. with 4 sccm of 2% H₂S gas.

Lanthanum sulfide thin films can be fabricated by replacing samarium chloride with lanthanum chloride in FIG. 5. The substrate 196 and the lanthanum chloride are heated to about 950° C. The overall chemical reaction equation is:

2LaCl₃(g)+3H₂S(g)→La₂S₃(s)+6HCl(g)

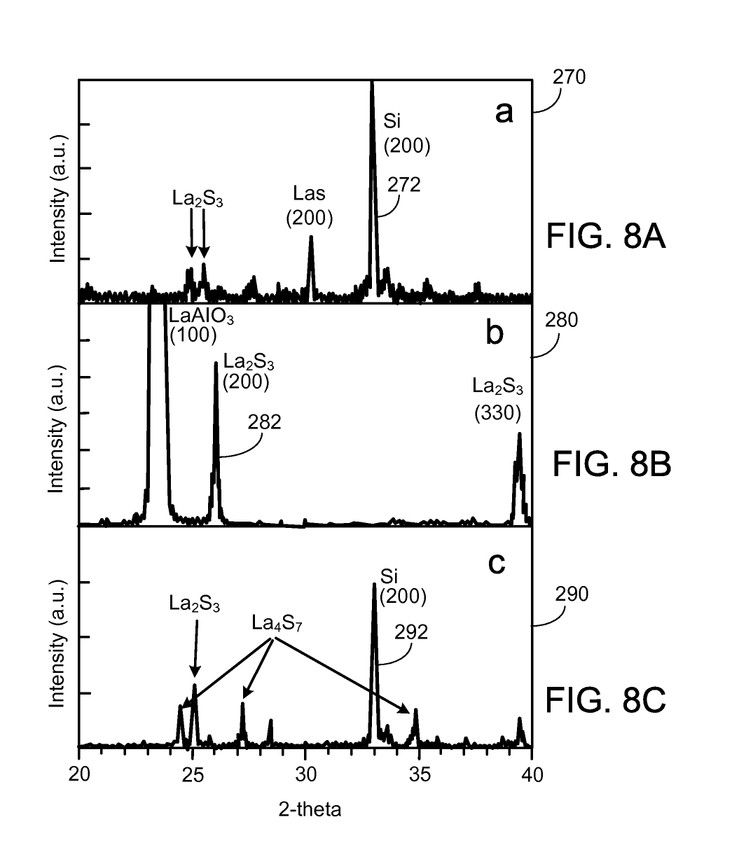

FIG. 8A is a graph 270 showing an x-ray diffraction pattern 272 of a lanthanum sulfide LaSₓ thin film grown with precursors LaCl₃(s) and H₂S(g), in which the flow rate of H₂S is 0.25 sccm. The substrate used in this example is a silicon wafer having a layer of silicon nitride.

FIG. 8B is a graph 280 showing an x-ray diffraction pattern 282 of a lanthanum sulfide LaSₓ thin film grown with precursors LaCl₃(s) and H₂S(g), in which the flow rate of H₂S(g) is 2 sccm. The substrate used in this example is (100) lanthanum aluminum oxide (LaAlO₃).

FIG. 8C is a graph 290 showing an x-ray diffraction pattern 292 of a lanthanum sulfide LaSₓ thin film grown with precursors LaCl₃(s) and H₂S(g), in which the flow rate of H₂S(g) is 15 sccm. The substrate used in this example is a silicon wafer having a layer of silicon nitride.

The graphs 270, 280, and 290 show that by controlling the flux of hydrogen sulfide from 0.25 to 15 sccm, preferential growth of a thin film having a mixture of LaS, La₂S₃ to La₄S₇ can be achieved.

The following describes organic photovoltaic (OPV) devices that use electrode materials made of rare-earth sulfides that have low work functions and are nearly transparent to visible light. Dye molecules or conjugated polymers are used to provide the solar power absorption medium in the organic photovoltaic devices. The combination of the organic polymer/dyes and inorganic rare earth sulfide nanostructures form an excitonic-based structure.

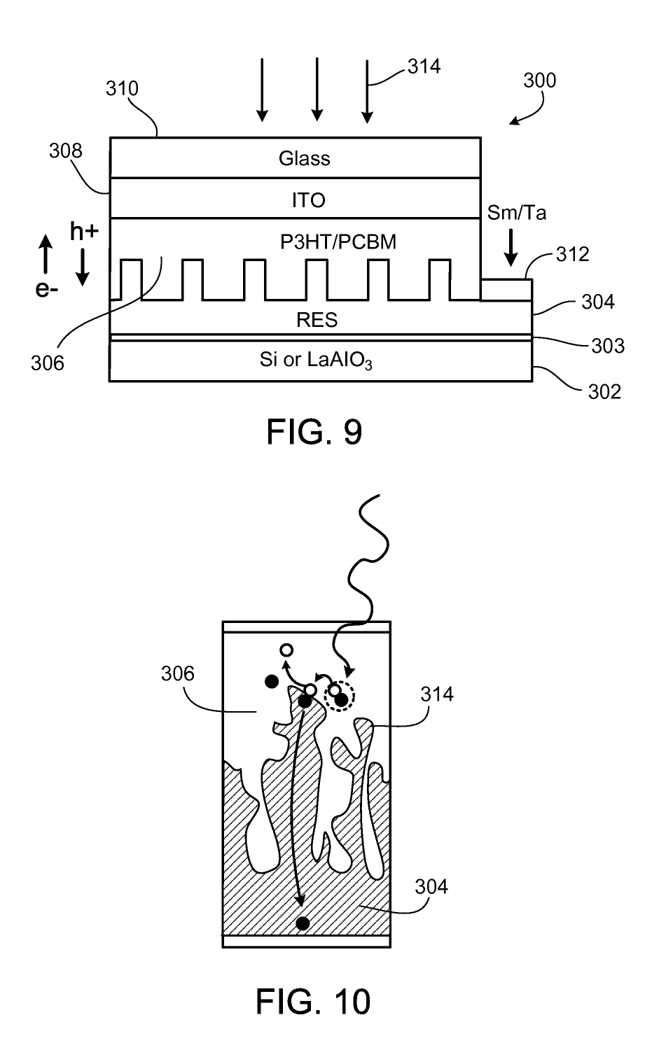

Referring to FIG. 9, in some implementations, an organic photovoltaic cell 300 includes a substrate 302, a growth layer 303, a rare earth sulfide nanowire layer 304, an organic polymer layer 306, a transparent conductive layer 308, and a protective glass layer 310. The substrate can be made of, for example, silicon. The growth layer 303 can be made of, e.g., zirconium nitride or titanium nitride. The rare earth sulfide 304 can be, e.g., samarium sulfide, which can be samarium sesquisulfide or samarium polysulfide. The organic polymer layer 306 can be made of, e.g., P3HT:PCBM (poly(3-hexylthiophene): [6,6]-phenyl C₆₁ butyric acid methyl ester). The transparent conductive layer 308 can be made of, e.g., indium tin oxide (ITO). An electrode contact 312 is provided for charge collection or injection to the rare earth sulfide layer 304. When the organic photovoltaic cell 300 is illuminated by light rays 314, electron-hole pairs are generated, in which the electrons are collected by the transparent conductive layer 308 and the holes are collected by the rare earth sulfide layer 304.

Referring to FIG. 10, the rare earth sulfide nanowire layer 304 has a forest of nanowires 314 embedded in the organic polymer 306. For example, samarium sulfide has a work function that approximately matches the valence band energy level of the conducting polymer. By embedding the samarium sulfide nanowires 314 in the organic polymer 306, shorter diffusion paths are provided for the low mobility electron-hole pairs generated in the polymer 306 for rapid charge collection. The samarium sulfide 304 functions as the positive electrode and enhances the collection of holes from the photo-excited polymers.

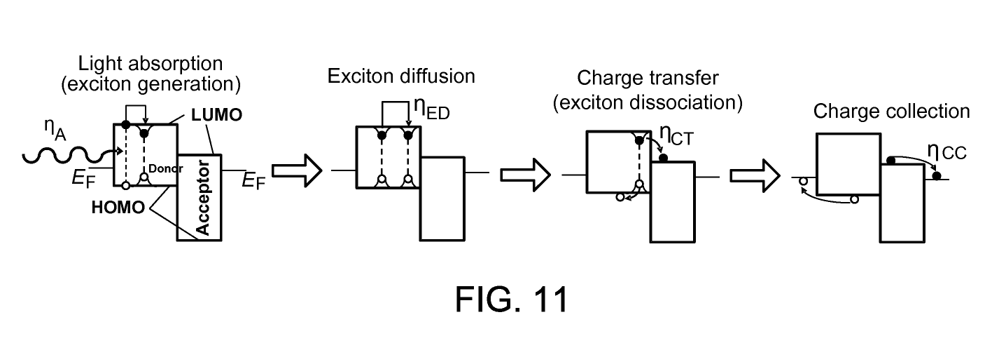

Referring to FIG. 11, the organic photovoltaic cell 300 operates based on an excitonic mechanism in which the electron-hole pairs are bound in the polymer molecule. When the bound state reaches an interface, it decomposes into the conventional charge carriers that are subsequently collected. The polymer material can be inexpensive and has high optical absorption coefficients. In organic photovoltaic devices, in order to control hole transport behavior and enhance device performance, the electrodes have Fermi levels matching the valence bands of the organic polymers. If the energy levels of the nanowires are not matched properly with the polymer absorber layer, injection of charge carriers back into the absorber layer may occur. Common electrode materials such as gold do not have low enough work function to match the valence bands of the conductive polymers. Easily oxidized metals such as calcium have low work functions but their reactivity imposes constraints on polymer-based device fabrication and stability. By comparison, rare-earth sulfides have low work functions (about 1-3 eV) and are more stable, suitable for use in organic photovoltaic devices.

Although some examples have been discussed above, other implementations and applications are also within the scope of the following claims. For example, the layer of p-type rare earth sulfide 106 in FIG. 1 can be doped with electron acceptor dopants (or p-type dopants), such as calcium, barium, or europium, to increase the number of electron holes. Because samarium can have a +2 or +3 valence state, elements that have a +2 valence state can be used as electron acceptor dopants. To fabricate a layer of samarium sulfide doped with calcium or barium, the samarium chloride 130 can be mixed with a small amount of calcium chloride or barium chloride and placed in the second section 138 of the chamber 136 in FIG. 2. The sulfur vapor reacts with the samarium chloride vapor and calcium chloride or barium chloride vapor, resulting in samarium sulfide deposited on the substrates 128, the samarium sulfide being doped with calcium or barium.

The layer of n-type rare earth sulfide 108 in FIG. 1 can be doped with electron donor dopants (or n-type dopants), such as cerium(IV) (or Ce4+) to increase the number of free electrons. Because lanthanum can have a +2 or +3 valence state, elements that have a +4 valence state can be used as electron donor dopants. To fabricate a layer of lanthanum sulfide doped with cerium(IV), lanthanum chloride can be mixed with cerium chloride and placed in the second section 138 of the chamber 136. The sulfur vapor reacts with the lanthanum chloride vapor and cerium chloride vapor, resulting in lanthanum sulfide deposited on the substrates 128, the lanthanum sulfide being doped with cerium(IV).

The values for the pressures and temperatures in the chambers 136 and 194 during reaction can be different from those described above. The distances of the substrates relative to the rare earth halide source material in FIG. 2 can be different from those described above. The thicknesses of the thin films can vary depending on application. The dimensions of the nanowires can also vary depending on application.

Rare earth sulfide thin films and rare earth sulfide nanowires can be used in lasers, light emitting diodes (LEDs), and thermoelectric devices. For example, samarium monosulfide has the following properties: high melting point, low work function, giant negative magnetoresistance, low resistance, large optical band gap, and fluctuating valence, and can be used in the following applications: holographic recorders, optical data storage devices, pressure sensitive devices, and electrochromic display devices. The rare earth sulfides can be used in electronic devices that need semiconducting materials having particular colors. The substrate used for growing rare earth sulfides can be made of materials different from those described above.

1. An apparatus comprising:
a photovoltaic cell comprising
a p-type thin film comprising a first rare earth sulfide,
an n-type thin film comprising a second rare earth sulfide, in which a p-n junction is formed between the p-type thin film and the n-type thin film,
a substrate, and
an at least partially transparent layer, in which the p-type and n-type thin films are deposited between the substrate and the at least partially transparent layer.

2. The apparatus of claim 1 in which each of the first and second rare earth sulfide comprises at least one of a first rare earth sesquisulfide (RE₂S₃) or polysulfide (RE₃S₄).

3. The apparatus of claim 1 in which the first rare earth sulfide comprises samarium.

4. The apparatus of claim 1 in which the second rare earth sulfide comprises at least one of yttrium, lanthanum, cerium, praseodymium, neodymium, gadolinium, terbium, dysprosium, or holmium.

5. The apparatus of claim 1 in which the p-type thin film comprises samarium sulfide doped with at least one of calcium, barium, or europium.

6. The apparatus of claim 1 in which the n-type thin film comprises lanthanum sulfide doped with cerium(IV).

7. The apparatus of claim 1 in which the photovoltaic cell comprises a growth layer formed on the substrate, and one of the p-type or n-type thin film is formed on the growth layer.

8. The apparatus of claim 7 in which the growth layer comprises at least one of zirconium nitride or titanium nitride.

9. The apparatus of claim 1 in which the substrate comprises a conductive material.

10. The apparatus of claim 1 in which the n-type thin film is closer to the at least partially transparent layer than the p-type thin film.

11. The apparatus of claim 1 in which the p-type thin film comprises a phase-pure rare earth sulfide.

12. The apparatus of claim 11 in which the p-type phase-pure rare earth sulfide is substantially composed of SmSₓ (x=1.3 to 1.5).

13. The apparatus of claim 1 in which the n-type thin film comprises a phase-pure rare earth sulfide.

14. The apparatus of claim 13 in which the n-type phase-pure rare earth sulfide is substantially composed of LaSₓ (x=1.3 to 1.5).

15. An apparatus comprising:
a substrate; and
a p-type semiconducting layer on the substrate, the p-type semiconducting layer comprising samarium sulfide nanowires.

16. The apparatus of claim 15, comprising a growth layer formed on the substrate, and the p-type semiconducting layer is formed on the growth layer.

17. The apparatus of claim 16 in which the growth layer comprises at least one of zirconium nitride or titanium nitride.

18. The apparatus of claim 15 in which the samarium sulfide nanowires comprise at least one of samarium sesquisulfide (Sm₂S₃) or polysulfide (Sm₃S₄) nanowires.

19. An apparatus comprising:
an organic photovoltaic cell comprising
a substrate,
a polymer film,
a p-type semiconducting layer comprising nanowires having samarium sulfide, and
an at least partially transparent layer, in which the polymer film and the p-type semiconducting layer are deposited between the substrate and the at least partially transparent layer.

20. The apparatus of claim 19, comprising a growth layer formed on the substrate, and the p-type semiconducting layer is formed on the growth layer.

21. The apparatus of claim 20 in which the growth layer comprises at least one of zirconium nitride or titanium nitride.

22. The apparatus of claim 19 in which the samarium sulfide comprises at least one of samarium sesquisulfide (Sm₂S₃) or polysulfide (Sm₃S₄).

23. A method comprising:
providing a growth layer on a substrate;
heating the substrate and the growth layer;
heating sulfur to form sulfur vapor;
heating samarium halide to form samarium halide vapor; and
forming a thin film of samarium sulfide on the growth layer, the samarium sulfide being generated from the sulfur and the samarium halide.

24. The method of claim 23 in which heating a samarium halide comprises heating at least one of samarium chloride, samarium iodide, or samarium bromide to form samarium chloride vapor, samarium iodide vapor, or samarium bromide vapor, respectively.

25. The method of claim 23 in which providing a growth layer on a substrate comprises providing at least one of a zirconium nitride layer or a titanium nitride layer on a substrate.

26. The method of claim 23 in which providing a growth layer on a substrate comprises providing a growth layer on a substrate that is conductive or semi-conductive.

27. The method of claim 23 in which the samarium sulfide comprises at least one of samarium sesquisulfide or samarium polysulfide.

28. The method of claim 23 in which heating sulfur comprises heating sulfur in a first chamber at a first temperature, and heating samarium halide comprises heating samarium halide in a second chamber at a second temperature, the second temperature being higher than the first temperature.

29. The method of claim 28, comprising controlling the temperature of the first chamber to control a stoichiometry and growth rate of the samarium sulfide thin film.

30. The method of claim 23, comprising placing the sulfur in an upstream heating chamber, and placing the substrate and the samarium halide in a downstream heating chamber, the downstream heating chamber having a temperature higher than that of the upstream heating chamber.

31. A method comprising:
providing a growth layer on a substrate;
heating the substrate and the growth layer;
heating sulfur to form sulfur vapor;
heating samarium halide to form samarium halide vapor; and
forming a textured film comprising samarium sulfide nanowires on the growth layer, the samarium sulfide nanowires being generated from the sulfur and the samarium halide.

32. The method of claim 31 in which providing a growth layer on a substrate comprises providing at least one of a zirconium nitride layer or a titanium nitride layer on a substrate.

33. The method of claim 31 in which the samarium sulfide comprises at least one of samarium sesquisulfide or samarium polysulfide.

34. The method of claim 31 in which heating a samarium halide comprises heating at least one of samarium chloride, samarium iodide, or samarium bromide to form samarium chloride vapor, samarium iodide vapor, or samarium bromide vapor, respectively.

35. A method comprising:
providing a growth layer on a substrate;
heating the substrate and the growth layer;
heating samarium halide to form samarium halide vapor;
providing hydrogen sulfide; and
forming a thin film of samarium sulfide on the growth layer, the samarium sulfide being generated from the sulfur and the samarium halide.

36. The method of claim 35 in which providing a growth layer on a substrate comprises providing at least one of a zirconium nitride layer or a titanium nitride layer on a substrate.

37. The method of claim 35, comprising controlling the flow rate of the hydrogen sulfide to control a stoichiometry and growth rate of the samarium sulfide thin film.

38. The method of claim 35 in which the samarium sulfide comprises at least one of samarium sesquisulfide or samarium polysulfide.

39. The method of claim 35 in which heating samarium halide comprises heating at least one of samarium chloride, samarium iodide, or samarium bromide to form samarium chloride vapor, samarium iodide vapor, or samarium bromide vapor, respectively.

40. A method comprising:
providing a growth layer on a substrate;
heating the substrate and the growth layer;
heating samarium halide to form samarium halide vapor;
providing hydrogen sulfide; and
forming a textured film comprising samarium sulfide nanowires on the growth layer, the samarium sulfide nanowires being generated from the sulfur and the samarium halide.

41. The method of claim 40 in which providing a growth layer on a substrate comprises providing at least one of a zirconium nitride layer or a titanium nitride layer on a substrate.

42. The method of claim 40 in which the samarium sulfide comprises at least one of samarium sesquisulfide or samarium polysulfide.

43. The method of claim 40 in which heating samarium halide comprises heating at least one of samarium chloride, samarium iodide, or samarium bromide to form samarium chloride vapor, samarium iodide vapor, or samarium bromide vapor, respectively.

44. A method of fabricating a photovoltaic cell, the method comprising:
providing a growth layer on a substrate;
forming a samarium sulfide thin film on the growth layer;
forming an n-type thin film on the samarium sulfide thin film, in which a p-n junction is formed between the n-type thin film and the samarium sulfide thin film; and
providing an at least partially transparent layer on the n-type thin film.

45. The method of claim 44 in which providing a growth layer on a substrate comprises providing at least one of a zirconium nitride layer or a titanium nitride layer on a substrate.

46. The method of claim 44 in which the samarium sulfide comprises at least one of samarium sesquisulfide or samarium polysulfide.

47. The method of claim 44 in which forming an n-type thin film comprises forming an n-type rare earth sulfide thin film.

48. The method of claim 47 in which forming an n-type thin film comprises forming a rare earth sulfide thin film that comprises at least one of yttrium, lanthanum, cerium, praseodymium, neodymium, gadolinium, terbium, dysprosium, or holmium.

49. A method of fabricating an organic photovoltaic cell, the method comprising:
providing a growth layer on a substrate;
forming a textured layer comprising samarium sulfide nanowires on the growth layer;
forming a polymer layer on the textured layer; and
providing an at least partially transparent layer on the polymer layer.

50. The method of claim 49 in which providing a growth layer on a substrate comprises providing at least one of a zirconium nitride layer or a titanium nitride layer on a substrate.

51. The method of claim 49 in which the samarium sulfide comprises at least one of samarium sesquisulfide or samarium polysulfide.

52. A method comprising:
providing at least one of a zirconium nitride layer or a titanium nitride layer on a substrate;
providing sulfur vapor;
providing rare earth halide vapor; and
generating a rare earth sulfide thin film on the zirconium nitride layer or the titanium nitride layer, the rare earth sulfide being formed based on a reaction between the sulfur vapor and the rare earth halide vapor.

53. The method of claim 52 in which providing rare earth halide vapor comprises providing rare earth halide vapor that comprises at least one of samarium, yttrium, lanthanum, cerium, praseodymium, neodymium, gadolinium, terbium, dysprosium, or holmium.

54. The method of claim 52 in which the rare earth sulfide comprises at least one of rare earth sesquisulfide or rare earth polysulfide.

55. The method of claim 52 in which providing rare earth halide vapor comprises provide at least one of samarium chloride vapor, samarium iodide vapor, or samarium bromide vapor.

56. A method comprising:
providing a first substrate and a second substrate in different locations of a chamber heated by a furnace, the chamber having a temperature gradient such that a local temperature of the first substrate is different from that of the second substrate;
providing sulfur vapor;
providing rare earth halide vapor;
depositing a rare earth sulfide thin film on the first substrate; and
forming rare earth sulfide nanowires on the second substrate;
wherein the rare earth sulfide is formed based on a reaction between the sulfur vapor and the rare earth halide vapor.

57. The method of claim 56 in which providing rare earth halide vapor comprises providing rare earth halide vapor that comprises at least one of samarium, yttrium, lanthanum, cerium, praseodymium, neodymium, gadolinium, terbium, dysprosium, or holmium.

58. The method of claim 56 in which the rare earth sulfide comprises at least one of rare earth sesquisulfide or rare earth polysulfide.

59. The method of claim 56 in which providing rare earth halide vapor comprises provide at least one of samarium chloride vapor, samarium iodide vapor, or samarium bromide vapor.
